(19) United States
(12) Patent Application Publication
(10) Pub. No.: US 2008/0271751 A1
(43) Pub. Date: Nov. 6, 2008

(54) APPARATUS AND METHOD FOR CLEANING SEMICONDUCTOR WAFER

(76) Inventor: Jun-Seok Lee, Goyang-si (KR)

Correspondence Address: SHERR & VAUGHN, PLLC, 620 HERNDON PARKWAY, SUITE 200, HERNDON, VA, 20170, US

(21) Appl. No.: 12/102,984

(22) Filed: Apr. 15, 2008

(30) Foreign Application Priority Data
May 2, 2007 (KR) 10-2007-0042571

(51) Int. Cl. B08B 7/04; H01L 21/00; B08B 5/02

(52) U.S. Cl. 134/1.3; 134/103.2

(57) ABSTRACT

An apparatus and a method for cleaning a semiconductor wafer including performing a first cleaning process for removing particles from the semiconductor wafer by injecting a cleaning gas in the chamber and on the semiconductor wafer and then performing a second cleaning process after the first cleaning process by generating an electric field in the chamber and over the semiconductor wafer.

The present application claims priority under 35 U.S.C. 119 and 35 U.S.C. 365 to Korean Patent Application No. P2007-0042571 (filed on May 2, 2007), which is hereby incorporated by reference in its entirety.

### BACKGROUND

Fabrication of semiconductor devices may include various process such as deposition, etching, ion implantation, etc. Specifically, a semiconductor device may be fabricated by depositing a plurality of thin layers, such as a polycrystalline layer, oxide layer, nitride layer, metal layer, etc., on and/or over a wafer, and thereafter patterning the wafer via photography, etching, ion implantation, etc.

Photolithography is a core technology of semiconductor fabrication and involves a process of forming a desired semiconductor device pattern on and/or over a wafer using a photo-mask. Photolithography may enable the quantity of light transmitted through a mask to be appropriately adjusted via delicate mask designing. Furthermore, with the use of technologies related to new photo-resists, scanners mounted with a high numerical-aperture lens, phase-shift masks, etc., more delicate implementation of the photo-lithography can become possible.

In particular, a technical limit of typical optical exposure devices can be overcome using an optical proximity correction technology related to the photo-lithography. Specifically, the optical proximity correction technology efficiently overcomes a limit of optical resolution with respect to semiconductor devices having non-repetitive and irregular pattern configurations such as logic devices, and at the same time, enables delicate and rapid patterning. In addition, the optical proximity correction technology can improve fabrication efficiency of micro-scale patterns while efficiently overcoming optical distortion, and also, can compensate for distortion of light due to optical exposure devices.

Meanwhile, fabrication of semiconductor devices can also include a cleaning process to remove reaction by-products such as polymers, photo-resist residues, etc., which are generated at sidewalls and bottom surfaces of contact holes formed via photolithography and etching processes.

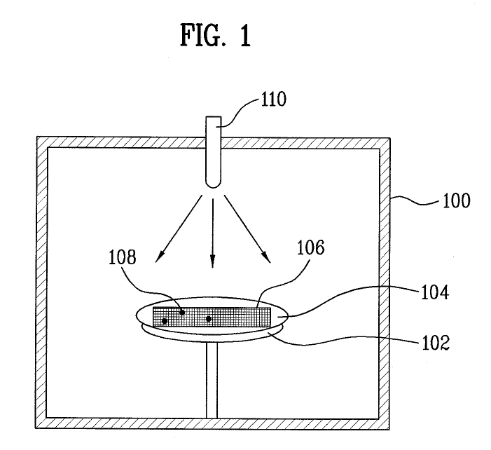

Example FIG. 1 illustrates an apparatus for cleaning semiconductor wafer 104 using a cleaning gas. As illustrated in example FIG. 1, when specific pattern 106 is formed on and/or over a surface of semiconductor wafer 104, which is placed on wafer chuck 102 located in cleaning device 100 (namely, cleaning chamber), a plurality of particles 108 may be generated due to formation of specific pattern 106. In such a cleaning apparatus, a cleaning gas, for example, N₂ gas, may be injected through gas injection nozzle 110 to implement a cleaning process for removing particles 108 from the surface of semiconductor wafer 104.

Despite performing a cleaning process using the injection of N₂ gas, it still is difficult to completely remove particles 108 that are electrically charged and adhered to pattern 106. Particularly, particles 108 that were not removed but still remain on pattern 106 may actually be moved via the injected N₂ gas to other locations on the surface of pattern 106 of semiconductor wafer 104. Accordingly, these particles 108 may serve as conductors, causing deterioration in the yield of the semiconductor devices in which such wafers 104 are placed.

### SUMMARY

Embodiments relate to the cleaning of a semiconductor device. More particularly, embodiments relate to an apparatus and a method for cleaning a semiconductor wafer, which is suitable for removing particles adhered to a pattern formed on the wafer during fabrication of a semiconductor device.

Embodiments relate to an apparatus and a method for cleaning a semiconductor wafer which can clean the semiconductor wafer using an electric field after injection of N₂ gas.

Embodiments relate to an apparatus and a method for cleaning a semiconductor wafer which can remove electrically-charged particles generated on a semiconductor wafer surface via a cleaning process using an electric field.

Embodiments relate to an apparatus for cleaning a semiconductor wafer that can include at least one of the following: a chamber for receiving a semiconductor wafer; a wafer retainer provided in the chamber for receiving and grounding the semiconductor wafer; a gas injector for performing a first cleaning process on the semiconductor wafer by injecting a cleaning gas in the chamber and on the surface of the semiconductor wafer; and an electric-field generator for performing a second cleaning process on the semiconductor wafer by generating an electric field in the chamber after completion of the first cleaning process by the gas injector.

Embodiments relate to a method for cleaning a semiconductor wafer that can include at least one of the following steps: providing a semiconductor wafer in a chamber and grounding the semiconductor wafer; and then performing a first cleaning process for removing particles from the semiconductor wafer by injecting a cleaning gas in the chamber and on the semiconductor wafer; and then performing a second cleaning process after the first cleaning process by generating an electric field in the chamber and over the semiconductor wafer.

Embodiments relate to a method for cleaning a semiconductor wafer that can include at least one of the following steps: providing a semiconductor wafer in a chamber and creating a vacuum in a chamber; removing particles from the semiconductor wafer by injecting a cleaning gas in the chamber and on the semiconductor wafer; and then removing the cleaning gas from the chamber; and then positively ionizing particles not removed by the cleaning gas and remaining on the semiconductor wafer by generating a negatively charged electric field in the chamber and over the semiconductor wafer; and then removing the positively ionized particles from the semiconductor wafer.

### DRAWINGS

Example FIG. 1 illustrates an apparatus for cleaning a semiconductor wafer using a cleaning gas.

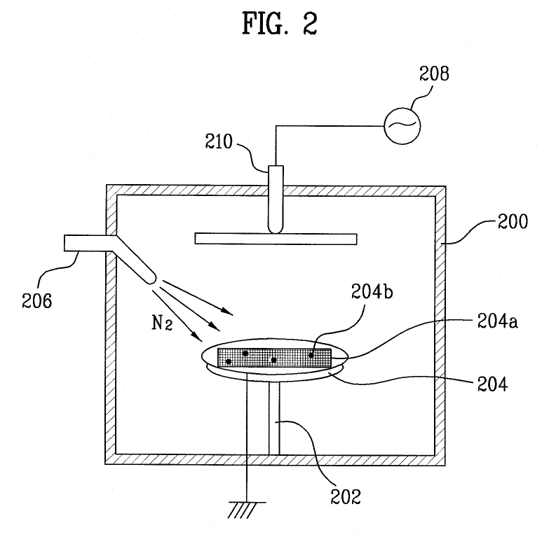

Example FIG. 2 illustrates a cleaning apparatus which performs an initial cleaning of a semiconductor wafer using a cleaning gas, in accordance with embodiments.

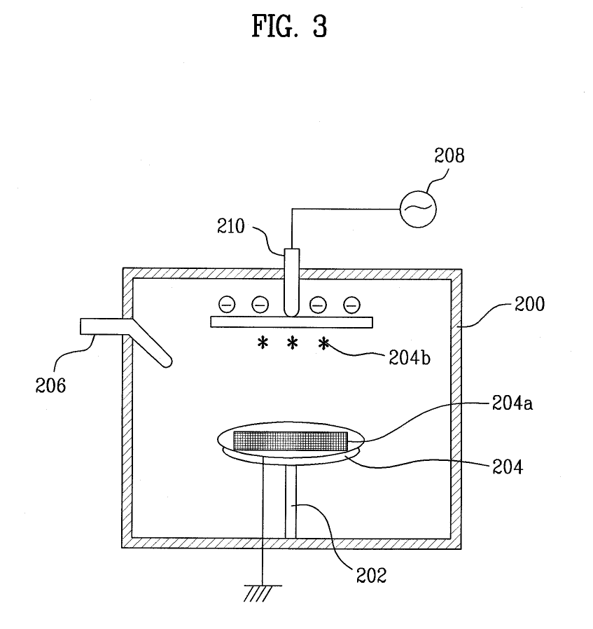

Example FIG. 3 illustrates a cleaning apparatus which performs a secondary cleaning of the semiconductor wafer using an electric field, in accordance with embodiments.

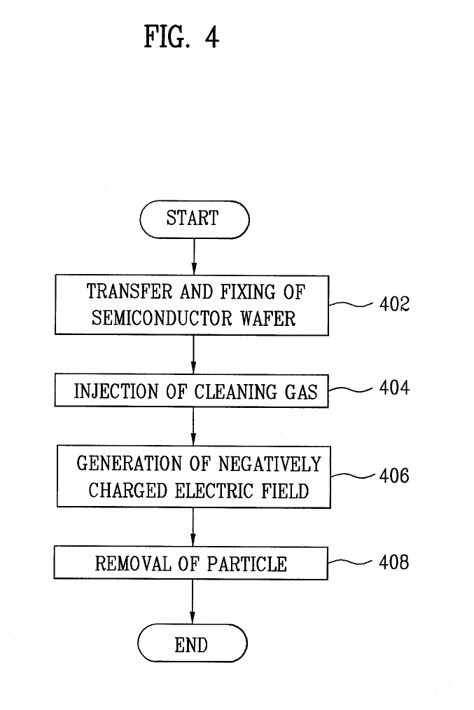

Example FIG. 4 is a flow chart which illustrates a method for cleaning a semiconductor wafer using a cleaning gas and an electric field, in accordance with embodiments.

### DESCRIPTION

Reference will now be made in detail to the preferred embodiments of the present invention, examples of which are illustrated in the accompanying drawings. Wherever possible, the same reference numbers will be used throughout the drawings to refer to the same or like parts.

Embodiments can include conducting a cleaning of a semiconductor wafer by removing particles caused during formation of a specific pattern on the semiconductor wafer. In accordance with embodiments, the semiconductor wafer can be grounded and fixed, and then a primary cleaning process is performed by injecting a cleaning gas and sequentially, a secondary cleaning process is performed by applying an electric field on and/or the semiconductor wafer.

As illustrated in example FIGS. 2 and 3, a cleaning apparatus can includes cleaning chamber 200, wafer retainer 202 including a wafer chuck which receives semiconductor wafer 204. Gas injector 206 is provided for injecting a cleaning gas into chamber 200 and an electric-field generator to generate a negatively charged electric field via electron gun 210 and DC power source 208. Here, a vacuum is maintained within cleaning chamber 200.

Gas injector 206 may be installed at a side wall of cleaning chamber 200 and can be configured to inject, at a specific angle relative to the surface of semiconductor wafer 204, a cleaning gas to a surface of semiconductor wafer 204. Alternatively, gas injector 206 can be installed at an upper wall of cleaning chamber 200, to inject a cleaning gas downward from above the surface of semiconductor wafer 204.

Wafer retainer 202 is provided for to maintain the fixed semiconductor wafer 204 in a grounded state. The electric-field generator may further include an electric-field generating plate provided at a side surface of electron gun 210 to generate an electric field covering over a wide area. During prior processing, semiconductor wafer 204 can be formed with a specific pattern 204a, and formation of specific pattern 204a may generate a plurality of particles 204b at the surface of semiconductor wafer 204.

As illustrated in shown in example FIGS. 2 and 3, in order to remove particles 204b generated at or on and/or over the surface of semiconductor wafer 204, the cleaning apparatus in accordance with embodiments sequentially implements a primary cleaning process using a cleaning gas and a secondary cleaning process using an electric field.

As illustrated in example FIG. 2, the primary cleaning process can be implemented by injecting a cleaning gas, using gas injector 206, onto the surface of semiconductor wafer 204 placed on wafer retainer 202. For example, the primary cleaning process can be implemented using N₂ gas under conditions of a temperature range between 22-25° C. and a flow rate range between 3-5 liter per minutes (lpm). After completing the primary cleaning process, the cleaning gas, namely, the N₂ gas, etc. remaining in cleaning chamber 200 can be pumped out.

Then, as illustrated in example FIG. 3, negative charges (i.e., negative ions) can be generated via electron gun 210 by power supplied from DC power source 208, and in turn, a resulting negatively charged electric field is dispersed via the electric-field generating plate provided at the distal end of electron gun 210. Thereby, the secondary cleaning process is implemented in such a way that particles 204b, generated at the surface of the grounded semiconductor wafer 204 are reciprocally positively ionized by the dispersed negatively charged electric field, and the resulting positively ionized particles 204b are moved to or adsorbed by a surface of the electric-field generating plate.

In summary, after primarily cleaning semiconductor wafer 204 using a suitable cleaning gas, a secondary cleaning process can then be implemented to permit particles 204b remaining at the surface of semiconductor wafer 204 to be adsorbed by the electric-field generator under the influence of a negatively charged electric field.

As a result of sequentially implementing the primary cleaning process via injection of a cleaning gas and the secondary cleaning process via generation of an electric field using a cleaning apparatus including gas injector 206 and an electric-field generator, particles caused during formation of a specific pattern on a semiconductor wafer can be efficiently removed.

As illustrated in example FIG. 4, a method for removing particles generated at a semiconductor wafer surface via the primary cleaning process using a cleaning gas and the secondary cleaning using an electric field using the afore-described semiconductor wafer cleaning apparatus will be described.

In accordance with embodiments, initial step 402 can include transferring and placing semiconductor wafer 204 which is formed with specific pattern 204a on wafer retainer 202 such that it is grounded.

Next, step 404 can include injecting at a predetermined angle a suitable cleaning gas such as N₂ gas, via gas injector 206 installed on a side region and/or upper region of cleaning chamber 200, to the surface of semiconductor wafer 204. Here, the cleaning gas can be injected under conditions of a temperature range between 22-25° C. and a flow rate in a range between 3-5 lpm. After completing the primary cleaning process, the cleaning gas remaining in cleaning chamber 200 can be pumped out via a predetermined pumping operation.

Thereafter, step 406 can include generating an electric field via an electric-field generator provided in an upper region of cleaning chamber 200. Specifically, negative charges can be generated via electron gun 210 from power supplied by DC power source 208. The generated negative charges can then be dispersed by a electric-field generating plate provided at the distal end of electron gun 210. For example, the negative charges generated via electron gun 210 and electric-field generating plate from the power supplied by DC power source 208, can be in a range of between 10 KeV to 50 KeV.

With the dispersed negatively charged electric field, particles 204b generated at the surface of grounded semiconductor wafer 204 are reciprocally positively ionized. Step 408 can include removing the positively ionized particles 204b from the surface of semiconductor wafer 204 and to the surface of the electric-field generating plate. Here, a vacuum can be maintained within cleaning chamber 200 during implementation of steps 402 to 408.

In this way, after grounding and fixing the semiconductor wafer, the semiconductor wafer is primarily cleaned by injecting a cleaning gas, and sequentially, is secondarily cleaned via generation of an electric field, so as to remove particles caused during formation of a specific pattern on the semiconductor wafer.

As apparent from the above description, as opposed to the method of only using a cleaning gas injected to a surface of a semiconductor wafer to remove particles caused during formation of a specific pattern thereon, in accordance with embodiments, such cleaning may include implementing a primary cleaning of injecting a cleaning gas and to a surface of a semiconductor wafer which has been grounded and fixed, but also implementing a secondary cleaning to remove particles not removed during the primary cleaning process. The secondary cleaning process can be performed by generating an electric filed in the chamber so that such remaining particles are absorbed by a surface of an electric-field generating plate. Accordingly, embodiments can have the effect of improving the yield of semiconductor devices.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a chamber for receiving a semiconductor wafer;
a wafer retainer provided in the chamber for receiving and grounding the semiconductor wafer;
a gas injector for performing a first cleaning process on the semiconductor wafer by injecting a cleaning gas in the chamber and on the surface of the semiconductor wafer; and
an electric-field generator for performing a second cleaning process on the semiconductor wafer by generating an electric field in the chamber after completion of the first cleaning process by the gas injector.

2. The apparatus of claim 1, wherein a vacuum is maintained within the chamber during injecting the cleaning gas and generating the electric field.

3. The apparatus of claim 1, wherein the cleaning gas comprises N₂ gas.

4. The apparatus of claim 3, wherein the N₂ gas is injected under conditions of a temperature range between 22-25° C. and a flow rate in a range between 3-5 lpm.

5. The apparatus of claim 1, wherein the gas injector is provided in the chamber spatially above the wafer retainer.

6. The apparatus of claim 1, wherein the gas injector injects the cleaning gas at a predetermined angle with respect to the surface of the semiconductor wafer.

7. The apparatus of claim 1, wherein the gas injector is provided in the chamber substantially perpendicular to the lateral surface of the semiconductor wafer.

8. The apparatus according to claim 1, wherein the electric-field generator comprises:
an electron gun for generating negative charges;
an electric-field generating plate connected to the electron gun for dispersing the negatively charged charges to create an electric field in the chamber; and
a DC power source for generating a DC power to the electron gun.

9. The apparatus of claim 8, wherein the negative charges are in a range of between 10 KeV to 50 KeV.

10. A method comprising:
providing a semiconductor wafer in a chamber and grounding the semiconductor wafer; and then
performing a first cleaning process to remove particles from the semiconductor wafer by injecting a cleaning gas in the chamber and on the semiconductor wafer; and then
performing a second cleaning process after performing the first cleaning process by generating an electric field in the chamber and over the semiconductor wafer.

11. The method of claim 10, further comprising, before performing the first cleaning process, creating a vacuum in the chamber, wherein the vacuum is maintained during the first cleaning process and the second cleaning process.

12. The method of claim 10, wherein the first cleaning process comprises injecting N₂ gas in the chamber and on the semiconductor wafer.

13. The method of claim 10, wherein the first cleaning process comprises injecting N₂ gas in the chamber and on the semiconductor wafer under conditions of a temperature range between 22-25° C. and a flow rate in a range between 3-5 lpm.

14. The method of claim 10, wherein the second cleaning process comprises generating a negatively charged electric field in the chamber.

15. The method of claim 10, wherein the second cleaning process comprises:
generating negative charges; and then
creating a negatively charged electric field in the chamber and over the semiconductor wafer using the negative charges.

16. The method of claim 15, wherein the generation of negative charges is implemented to generate the negative charges in a range of 10 KeV to 50 KeV.

17. The method of claim 10, wherein the second cleaning process comprises:
positively ionizing the particles on the semiconductor wafer by generating a negatively charged electric field in the chamber and over the semiconductor wafer; and then
removing the positively ionized particles from the semiconductor wafer.

18. The method of claim 10, wherein the first cleaning process comprises injecting a cleaning gas at a predetermined angle relative to the surface of the semiconductor wafer

19. The method of claim 10, further comprising, after performing the first cleaning process and before performing the second cleaning process, removing the cleaning gas from the chamber.

20. A method comprising:
providing a semiconductor wafer in a chamber and creating a vacuum in a chamber;
removing particles from the semiconductor wafer by injecting a cleaning gas in the chamber and on the semiconductor wafer; and then
removing the cleaning gas from the chamber; and then
positively ionizing particles not removed by the cleaning gas and remaining on the semiconductor wafer by generating a negatively charged electric field in the chamber and over the semiconductor wafer; and then
removing the positively ionized particles from the semiconductor wafer.
